(19) United States
(12) Patent Application Publication
(10) Pub. No.: US 2026/0182211 A1
(43) Pub. Date: Jun. 25, 2026

(54) METHOD OF MANUFACTURING DISPLAY MODULE, DISPLAY MODULE, AND ELECTRONIC DEVICE INCLUDING THE SAME

(71) Applicant: Samsung Display Co., Ltd., Yongin-Si (KR)

(72) Inventors: Kinyeng Kang, Yongin-si (KR); Chanju Park, Yongin-si (KR); Sungeun Lee, Yongin-si (KR); Hyoengki Kim, Yongin-si (KR); Keunkyu Song, Yongin-si (KR)

(21) Appl. No.: 19/220,643

(22) Filed: May 28, 2025

(30) Foreign Application Priority Data
Dec. 19, 2024 (KR) 10-2024-0191727

(51) Int. Cl. H10K 59/80; H10K 59/12; H10K 59/40

(52) U.S. Cl. CPC H10K 59/873; H10K 59/1201; H10K 59/40

(57) ABSTRACT

A method of manufacturing a display module, a display module, and an electronic device including the display module for implementing a slim bezel are provided. The method includes forming a display layer on a substrate that has a display area and a peripheral area, forming an encapsulation layer on the display layer, removing an edge portion of the encapsulation layer to leave a remaining portion of the encapsulation layer, forming a through hole in the remaining portion of the encapsulation layer, disposing a conductive material in the through hole, and forming a touch sensor layer on the encapsulation layer.

### CROSS-REFERENCE TO RELATED APPLICATION

This application is based on and claims priority, under 35 U.S.C. § 119, to Korean Patent Application No. 10-2024-0191727 filed on Dec. 19, 2024 in the Korean Intellectual Property Office, the disclosure of which is incorporated by reference herein in its entirety.

### BACKGROUND

### 1. Field

One or more embodiments relate to a method for manufacturing a display module, a display module, and an electronic device including the display module, and more particularly, to a method for manufacturing a display module for implementing a slim bezel, a display module, and an electronic device including the display module.

### 2. Description of the Related Art

A display module is a device that receives information for an image and displays the image. The display module may be used as a display portion of small products such as mobile phones, and may be used as a display portion of large products such as televisions.

The display module includes a plurality of pixels that emit light by receiving electrical signals to display images to the outside. Each pixel includes a light emitting element. For example, in the case of an organic light emitting display device, each pixel includes an organic light emitting diode (OLED) as the light emitting element. Generally, an organic light emitting display device forms a thin film transistor (TFT) and an organic light emitting diode on a substrate, and the organic light emitting diode operates by emitting light.

Meanwhile, an electronic device may provide a visual interface required by a user through a display module.

### SUMMARY

Some embodiments provide a method of manufacturing a display module for implementing a slim bezel, a display module, and an electronic device including the display module to solve various problems. The scope of the embodiments is not limited by the examples provided herein.

Additional aspects will be set forth in part in the description which follows and, in part, will be apparent from the description, or may be learned by practice of the presented embodiments of the disclosure.

According to an embodiment, a method of manufacturing a display module may include forming a display layer on a substrate that has a display area and a peripheral area, forming an encapsulation layer on the display layer, removing an edge portion of the encapsulation layer to leave a remaining portion of the encapsulation layer, forming a through hole through the remaining portion of the encapsulation layer on the peripheral area, disposing a conductive material in the through hole, and forming a touch sensor layer on the remaining portion of the encapsulation layer.

The touch sensor layer may contact the conductive material that is disposed in the through hole.

The display layer may include a semiconductor layer on the substrate, a gate layer on the semiconductor layer, a first conductive layer on the gate layer, a second conductive layer on the first conductive layer, and a pixel electrode on the second conductive layer.

The conductive material may contact a portion of the first conductive layer of the display layer.

The forming of the touch sensor layer may include covering a side surface of the remaining portion of the encapsulation layer with the touch sensor layer.

The forming of the through hole may include using a hard mask.

The encapsulation layer may include a first inorganic encapsulation layer disposed on the display layer, an organic encapsulation layer disposed on the first inorganic encapsulation layer, and a second inorganic encapsulation layer disposed on the organic encapsulation layer.

The forming of the through hole may include forming a first through hole in the first inorganic encapsulation layer, forming a second through hole in the organic encapsulation layer, and forming a third through hole in the second inorganic encapsulation layer.

The first through hole, the second hole, and the third through hole may align to form a continuous through hole.

The conductive material may be disposed in the first through hole, the second through hole, and the third through hole.

The through hole may not overlap with the first pixel electrode.

There may also be a second pixel electrode disposed in a same layer as the first pixel electrode, wherein the through hole is disposed between the first pixel electrode and the second pixel electrode.

According to an embodiment, a display module may include a substrate having a display area and a peripheral area, a display layer disposed on the substrate, an encapsulation layer disposed on the display layer and having a step difference with respect to the display layer, a conductive body including a conductive material extending through the encapsulation layer in the peripheral area, and a touch sensor layer disposed on the encapsulation layer, contacting an upper surface of the conductive body, and covering an upper surface and a side surface of the encapsulation layer.

The display layer may include a semiconductor layer disposed on the substrate, a gate layer disposed on the semiconductor layer, a first conductive layer disposed on the gate layer, a second conductive layer disposed on the first conductive layer, and a pixel electrode disposed on the second conductive layer.

A lower surface of the conductive body may contact a touch routing line disposed in a same layer as the first conductive layer.

The conductive body may be distanced from the first pixel electrode in plan view.

Where the pixel electrode is a first pixel electrode, there may be a second pixel electrode disposed in a same layer as the first pixel electrode, wherein the conductive body is disposed between the first pixel electrode and the second pixel electrode.

The encapsulation layer may include a first inorganic encapsulation layer disposed on the display layer and having a first through hole, an organic encapsulation layer disposed on the first inorganic encapsulation layer and having a second through hole, and a second inorganic encapsulation layer disposed on the organic encapsulation layer and having a third through hole.

The first through hole, the second through hole, and the third through hole may form a continuous through hole, and the conductive body may be disposed inside the first through hole, the second through hole, and the third through hole.

According to an embodiment, an electronic device may include a memory storing data information, a processor generating a data signal and/or a control signal based on the data information, and a display module operating based on the data signal and/or the control signal, wherein the display module includes a substrate having a display area and a peripheral area, a display layer disposed on the substrate, an encapsulation layer disposed on the display layer and having a step difference with respect to the display layer, a conductive body including a conductive material extending through the encapsulation layer in the peripheral area, and a touch sensor layer disposed on the encapsulation layer, contacting an upper surface of the conductive body, and covering an upper surface and a side surface of the encapsulation layer.

### BRIEF DESCRIPTION OF THE DRAWINGS

The above and other aspects, features, and advantages of certain embodiments of the disclosure will be more apparent from the following description taken in conjunction with the accompanying drawings, in which:

The above-described features will be more clearly understood from the following detailed description of exemplary and non-limiting embodiments taken in conjunction with the accompanying drawings.

FIG. 1 is a plan view schematically illustrating a display module according to an embodiment;

FIG. 2 is an example of an equivalent circuit diagram of a sub-pixel of a display device;

FIG. 3 is a cross-sectional view taken along line II-II′ of FIG. 1;

FIGS. 4, 5, 6, 7, and 8 sequentially illustrate manufacturing processes for the region that represented by cross sectional views taken along line I-I′ of FIG. 1;

FIG. 9 is a plan view schematically illustrating a stretchable display module according to an embodiment;

FIG. 10 is a cross-sectional view illustrating an example of a cross-section taken along line III-III′;

FIG. 11 is a block diagram of an electronic device according to an embodiment; and

FIG. 12 depict schematic views of electronic devices according to various embodiments.

### DETAILED DESCRIPTION

Reference will now be made in detail to embodiments, examples of which are

illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Some embodiments may have various modifications and several embodiments, and specific embodiments will be illustrated in the drawings and described in detail in the detailed description. Effects and features of the embodiments, and methods for achieving them will become apparent from embodiments described below with reference to the drawings. However, the embodiments are not limited to the embodiments disclosed below but may be implemented in various forms.

Hereinafter, embodiments will be described in detail with reference to the accompanying drawings. within description that references the drawings, the same or corresponding components will be given the same reference numerals and redundant descriptions thereof will be omitted.

In the following embodiments, terms such as first, second, etc. are used not in a limiting sense but for the purpose of distinguishing one component from another component. Also, in the following embodiments, a singular expression includes a plural expression unless the context clearly indicates otherwise.

In the following embodiments, when various components such as a layer, film, region, plate, etc. are described as being “on” another component, this includes not only cases where they are “directly on” the other component but also cases where other components are interposed therebetween.

Also, for convenience of illustration, size of components may be exaggerated or reduced in the drawings. For example, the size and thickness of each component shown in the drawings are arbitrarily shown for convenience of description, and therefore the embodiments are not necessarily limited to what is shown.

In the following embodiments, terms such as “include” or “have” mean that features or components described in the specification exist, and do not preclude the possibility that one or more other features or components may be added.

In the following embodiments, when a portion of a film, region, component, etc. is described as being on or above another portion, this includes not only cases where it is directly on the other portion but also cases where other films, regions, components, etc. are interposed therebetween.

When an embodiment may be implemented differently, a specific process order may be performed differently from the order in which it is described. For example, two processes described consecutively may be performed substantially simultaneously or in a reverse order from the described order.

In the present specification, the phrase “A and/or B” encompasses the possibilities of just A, just B, or both A and B. Similarly, the expression “at least one of A and B” encompasses the possibilities of just A, just B, or both A and B.

In the following embodiments, when films, regions, components, etc. are described as being connected, this includes cases where they are directly connected, and/or cases where they are indirectly connected with other films, regions, components, etc. interposed therebetween. For example, in the present specification, when films, regions, components, etc. are described as being electrically connected, this indicates cases where they are directly electrically connected, and/or cases where they are indirectly electrically connected with other films, regions, components, etc. interposed therebetween.

In the following embodiments, x-axis, y-axis, and z-axis are not limited to three axes in an orthogonal coordinate system but may be interpreted in a broader sense including the orthogonal coordinate system. For example, x-axis, y-axis, and z-axis may be orthogonal to each other, or may refer to different directions that are not orthogonal to each other.

Based on the above descriptions, a method for manufacturing a display module and a display module according to an embodiment will be described in detail below.

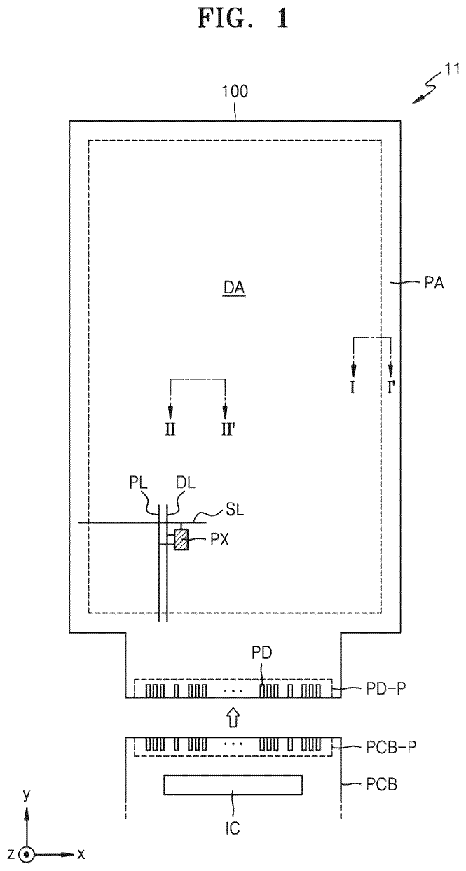

FIG. 1 is a plan view schematically illustrating a display module according to an embodiment.

As illustrated in FIG. 1, a display module 11 includes a display area DA and a peripheral area PA disposed outside the display area DA. In FIG. 1, the display area DA is illustrated as having a rectangular shape, but the embodiments are not limited to the rectangular shape of the display area DA. For example, the display area DA may have various shapes such as circular, oval, polygonal, or specific geometric shapes.

The display area DA is a portion for displaying images, and a plurality of sub-pixels PX may be disposed in the display area DA. Each sub-pixel PX may include a display element such as an organic light emitting device. For example, each sub-pixel PX may emit red, green, or blue light. The sub-pixels PX may be connected to a pixel circuit including a thin film transistor (TFT), a storage capacitor, and the like. The pixel circuit may be connected to a scan line SL transmitting a scan signal, a data line DL crossing the scan line SL and transmitting a data signal, and a driving voltage line PL supplying a driving voltage. For example, the data line DL and the driving voltage line PL may extend in a y-axis direction (hereinafter, referred to as a first direction), and the scan line SL may extend in an x-axis direction (hereinafter, referred to as a second direction).

The sub-pixel PX may emit light with a luminance corresponding to an electrical signal received from the data line DL. The display area DA may display a predetermined image through light emitted from the sub-pixel PX. For reference, the sub-pixel PX may be defined as a light emitting region that emits light of one color among red, green, and blue.

The peripheral area PA is a region where sub-pixels PX are not disposed, and may be a region that does not display images. Power supply lines for driving the sub-pixel PX may be disposed in the peripheral area PA. Also, pads PD may be disposed in the peripheral area PA, and the peripheral area PA may include a pad region PD-P where the pads PD are disposed.

An integrated circuit (IC) such as a driver IC may be mounted on a printed circuit board (PCB) including a driving circuit portion, and terminals electrically connected to the IC may be disposed in a terminal region PCB-P of the PCB. The terminal region PCB-P corresponds to the pad region PD-P, and the pads PD may be electrically connected to terminals of the terminal region PCB-P in the peripheral area PA.

For reference, since the display module 11 includes a substrate 100, the substrate 100 may include the display area DA and the peripheral area PA. Details about the substrate 100 will be described below.

Also, a plurality of transistors may be disposed in the display area DA. Depending on the type (N-type or P-type) and operating conditions of a transistor, a first terminal of the plurality of transistors may be a source electrode or a drain electrode, and a second terminal may be an electrode different from the first terminal among the source electrode and the drain electrode. For example, when the first terminal is the source electrode, the second terminal may be the drain electrode.

Hereinafter, although an organic light emitting display device will be described as an example of a display device according to an embodiment, the display device is not limited to the organic light emitting display device. In some embodiments, the display device may be an inorganic light emitting display (or inorganic EL display device), or a display device such as a quantum dot light emitting display. For example, a light emitting layer included in the display device may include organic material or inorganic material. In some cases, the display device may include a light emitting layer and quantum dots positioned in the path of light emitted from the light emitting layer.

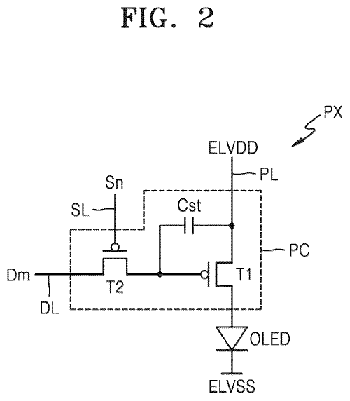

FIG. 2 is an example of an equivalent circuit diagram schematically illustrating a sub-pixel of the display device of FIG. 1. The equivalent circuit diagram of FIG. 2 is a basic equivalent circuit diagram, and at least one of various modified equivalent circuit diagrams applying the equivalent circuit diagram of FIG. 2 may be applied to the display module according to an embodiment.

For convenience of description, although a pMOS type thin film transistor is illustrated in FIG. 2, the pixel circuit mentioned in the specification is not limited to the pMOS type thin film transistor and may be modified in various ways.

As illustrated in FIG. 2, each sub-pixel PX may include a pixel circuit PC connected to a scan line SL and a data line DL, and a light emitting element OLED connected to the pixel circuit PC.

For example, the pixel circuit PC may include a driving thin film transistor T1, a switching thin film transistor T2, and a storage capacitor Cst. The switching thin film transistor T2 is connected to the scan line SL and the data line DL, and may transfer a data signal Dm input through the data line DL to the driving thin film transistor T1 according to a scan signal Sn input through the scan line SL.

For example, the driving thin film transistor T1 is a thin film transistor for driving, and the switching thin film transistor T2 may be a thin film transistor for switching operation.

For example, the storage capacitor Cst is connected to the switching thin film transistor T2 and the driving voltage line PL, and may store a voltage corresponding to a difference between a voltage received from the switching thin film transistor T2 and a first power voltage ELVDD (or driving voltage) supplied to the driving voltage line PL.

For example, the driving thin film transistor T1 is connected to the driving voltage line PL and the storage capacitor Cst, and may control a driving current flowing from the driving voltage line PL to the light emitting element OLED in correspondence with a voltage value stored in the storage capacitor Cst. The light emitting element OLED may emit light having a predetermined luminance by the driving current.

The light emitting element OLED may receive a second power voltage ELVSS (or common voltage). For example, the light emitting element OLED may receive the second power voltage ELVSS (or common voltage) through an opposing electrode (cathode), and the light emitting element OLED may emit light having a predetermined luminance by a driving current according to a voltage difference between the first power voltage ELVDD (or driving voltage) and the second power voltage ELVSS (or common voltage).

Although FIG. 2 describes a case where the pixel circuit PC includes two thin film transistors and one storage capacitor Cst, the embodiments are not limited to the pixel circuit configuration with two thin film transistors and one storage capacitor. For example, the pixel circuit PC may include not only two or more capacitors but also three or more thin film transistors.

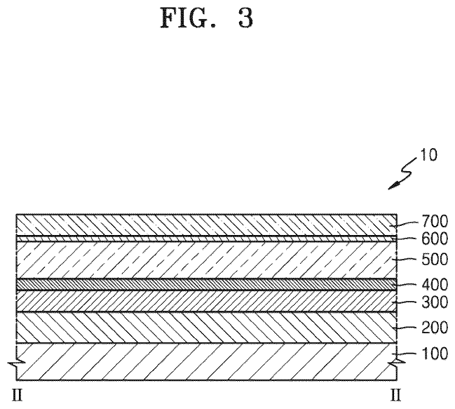

FIG. 3 is a cross-sectional view taken along line II-II′ of FIG. 1.

As illustrated in FIG. 3, the display device includes a display layer 200 forming a display area DA on a substrate 100. The display layer 200 includes sub-pixels each having a light emitting diode and may provide a predetermined image.

An encapsulation layer 300 may cover the display layer 200. The encapsulation layer 300 may protect the display layer 200 from external moisture or oxygen, and a touch sensor layer 400 may be disposed on the encapsulation layer 300.

The touch sensor layer 400 may include a plurality of sensor electrodes having conductivity. For example, the touch sensor layer 400 may be a capacitive type. The touch sensor layer 400 may be used to output coordinates of a position where an object such as a user's hand approaches or contacts by using a change in capacitance that occurs when the object approaches or contacts the surface of the touch sensor layer 400.

An optical functional layer 500 may be disposed on the touch sensor layer 400. The optical functional layer 500 may include an anti-reflection functional layer. The anti-reflection functional layer may include a retarder and a polarizer, or may include a black matrix and a color filter.

A cover window 700 may be disposed on the optical functional layer 500 with an adhesive layer 600 interposed therebetween. The adhesive layer 600 may include an optical clear adhesive.

The cover window 700 may include a flexible window. For example, the cover window 700 may include a plastic window such as polyimide, or an ultra-thin glass window.

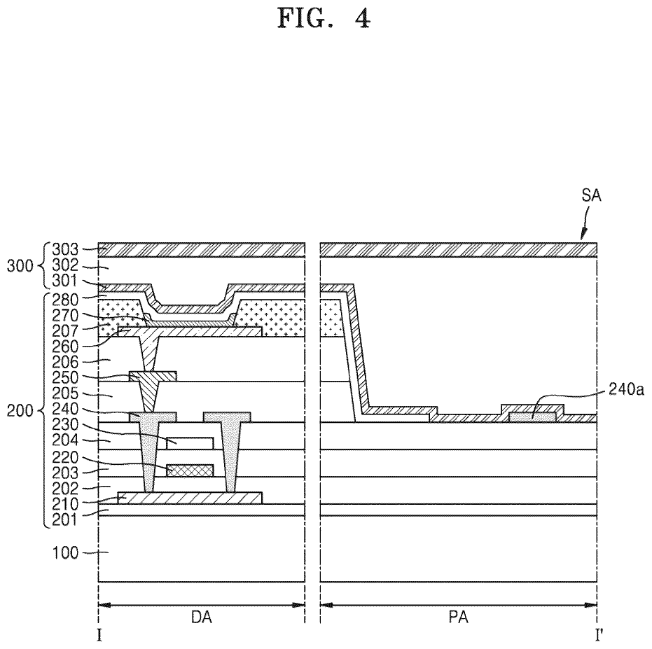

FIGS. 4 to 8 are cross-sectional views sequentially illustrating manufacturing processes taken along line I-I′ of FIG. 1.

Referring to FIGS. 4 to 8, the substrate 100 may include areas corresponding to the display area DA and the peripheral area PA outside the display area DA as described above. The substrate 100 may include various materials having flexible or bendable characteristics. For example, the substrate 100 may include glass, metal, or polymer resin. Also, the substrate 100 may include polymer resins such as polyethersulphone, polyacrylate, polyetherimide, polyethylene naphthalate, polyethylene terephthalate, polyphenylene sulfide, polyarylate, polyimide, polycarbonate, or cellulose acetate propionate.

The substrate 100 may have various modifications, such as having a multilayer structure including two layers each containing such polymer resin and a barrier layer containing inorganic material (such as silicon oxide, silicon nitride, silicon oxynitride) interposed between those layers.

A buffer layer 201 may be disposed on the substrate 100. The buffer layer 201 may include inorganic materials such as silicon oxide, silicon nitride, and/or silicon oxynitride, and may be interposed between the substrate 100 and a semiconductor layer 210. The buffer layer 201 may be formed through chemical vapor deposition (CVD) or atomic layer deposition (ALD). The buffer layer 201 may prevent diffusion of impurity ions, prevent penetration of moisture or external air, and control the rate of heat supply during crystallization process for forming the semiconductor layer 210 to allow uniform crystallization of the semiconductor layer 210.

The semiconductor layer 210 may be disposed on the buffer layer 201. The semiconductor layer 210 may be made of polysilicon (for example, low-temperature polycrystalline silicon) and may include a channel region where impurities are not doped, and source-drain regions formed by doping impurities on both sides of the channel region. Here, the impurities vary depending on the type of thin film transistor, and may be N-type impurities or P-type impurities.

A first gate insulating layer 202 may be disposed on the semiconductor layer 210. The first gate insulating layer 202 may be a configuration for securing insulation between the semiconductor layer 210 and a first gate layer 220. The first gate insulating layer 202 may include inorganic materials such as silicon oxide, silicon nitride, and/or silicon oxynitride, and may be interposed between the semiconductor layer 210 and the first gate layer 220. The first gate insulating layer 202 may have a formation corresponding to an entire surface of the substrate 100, and may have a structure where contact holes are formed in predetermined portions. The first gate insulating layer 202 may be formed through chemical vapor deposition (CVD) or atomic layer deposition (ALD).

The first gate layer 220 may be disposed on the first gate insulating layer 202. The first gate layer 220 may be disposed at a position vertically overlapping with the semiconductor layer 210, and may include at least one metal selected from molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), and copper (Cu).

A second gate insulating layer 203 may be disposed on the first gate layer 220. The second gate insulating layer 203 electrically insulates the first gate layer 220 from a second gate layer 230. The second gate insulating layer 203 may include inorganic materials such as silicon oxide, silicon nitride, and/or silicon oxynitride, and may be interposed between the first gate layer 220 and the second gate layer 230. The second gate insulating layer 203 may have a formation corresponding to an entire surface of the substrate 100, and may have a structure where contact holes are formed in predetermined portions. The second gate insulating layer 203 may be formed through chemical vapor deposition (CVD) or atomic layer deposition (ALD).

The second gate layer 230 may be disposed on the second gate insulating layer 203. The second gate layer 230 may be disposed at a position overlapping with the first gate layer 220 in a plan view, and may include at least one metal selected from molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), and copper (Cu).

An interlayer insulating film 204 may be disposed on the second gate layer 230. The interlayer insulating film 204 may cover the second gate layer 230. The interlayer insulating film 204 may be made of inorganic material. For example, the interlayer insulating film 204 may be a metal oxide or metal nitride, and specifically, the inorganic material may include silicon oxide (SiO2), silicon nitride (SiNx), silicon oxynitride (SiON), aluminum oxide (Al2O3), titanium oxide (TiO2), tantalum oxide (Ta2O5), hafnium oxide (HfO2), or zinc oxide (ZnO2). For example, the interlayer insulating film 204 may be have a dual-layer structure of SiOx/SiNy or SiNx/SiOy.

A first conductive layer 240 may be disposed on the interlayer insulating film 204. The first conductive layer 240 may serve as an electrode connected to a source/drain region of the semiconductor layer 210 through a through hole included in the interlayer insulating film 204.

The first conductive layer 240 may include one or more metals selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). For example, the first conductive layer 240 may include a Ti layer, an Al layer, and/or a Cu layer. For example, the first conductive layer 240 may include a Ti/Al/Ti triple-layer structure.

A first organic insulating layer 205 may be disposed on the first conductive layer 240. The first organic insulating layer 205 may be an organic insulating layer that covers the upper portion of the first conductive layer 240 and has a substantially planar upper surface, serving as a planarization layer. The first organic insulating layer 205 may include, for example, organic materials such as acryl, benzocyclobutene (BCB), or hexamethyldisiloxane (HMDSO). The first organic insulating layer 205 may have various modifications; for example, it may be a single layer structure or multiple-layer structure.

A second conductive layer 250 may be disposed on the first organic insulating layer 205. The second conductive layer 250 may be connected to a portion of the first conductive layer 240 that is connected to the semiconductor layer 210 through a through hole included in the first organic insulating layer 205, and may serve as an electrode through the connection between the second conductive layer and the first conductive layer. The second conductive layer 250 may include one or more metals selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). For example, the second conductive layer 250 may include a Ti layer, an Al layer, and/or a Cu layer. For example, the second conductive layer 250 may have a Ti/Al/Ti structure.

A second organic insulating layer 206 may be disposed on the second conductive layer 250. The second organic insulating layer 206 may be an organic insulating layer that covers the upper portion of the second conductive layer 250 and has a substantially planar upper surface, serving as a planarization layer. The second organic insulating layer 206 may include, for example, organic materials such as acryl, benzocyclobutene (BCB), or hexamethyldisiloxane (HMDSO). The second organic insulating layer 206 may have various modifications, such as being configured as a single layer or multiple layers.

A pixel electrode layer 260 may be disposed on the second organic insulating layer 206. The pixel electrode layer 260 may be connected to the second conductive layer 250 through a contact hole formed in the second organic insulating layer 206. A display element may be disposed on the pixel electrode layer 260. For example, a light emitting element using organic material may be used as the display element. For example, the pixel electrode layer 260 may include a transparent conductive layer formed of transparent conductive oxide such as indium tin oxide (ITO), indium oxide (In2O3), or indium zinc oxide (IZO), and/or a reflection layer formed of metal such as aluminum (Al) or silver (Ag). For example, the pixel electrode layer 260 may have a three-layer structure of ITO/Ag/ITO.

A pixel defining layer 207 may be disposed on the upper portion of the second organic insulating layer 206 and may be disposed to cover edges of pixel electrodes implemented for each sub-pixel PX through the pixel electrode layer 260. For example, the pixel defining layer 207 may cover edges of pixel electrodes implemented for each sub-pixel PX. The pixel defining layer 207 may have an opening corresponding to each sub-pixel PX, and the opening may be formed such that at least a central portion of the pixel electrode implemented for each sub-pixel is exposed. The opening may be defined by the pixel defining layer 207.

For example, the pixel defining layer 207 may include organic materials such as polyimide or hexamethyldisiloxane (HMDSO). A spacer (not shown) may be disposed on the pixel defining layer 207.

An intermediate layer 270 and an opposing electrode 280 may be disposed on the aforementioned opening. The intermediate layer 270 includes low molecular weight or high molecular weight material, and when including low molecular weight material, the intermediate layer 270 may include a hole injection layer, a hole transport layer, an emission layer, an electron transport layer, and/or an electron injection layer. When the intermediate layer 270 includes high molecular weight material, the intermediate layer 270 may generally have a structure including a hole transport layer and an emission layer.

The structure of the intermediate layer 270 is not limited to what is described above and may have various structures. For example, at least one of the layers constituting the intermediate layer 270 may be formed integrally with the opposing electrode 280. As another embodiment, the intermediate layer 270 may have a patterned layer corresponding to each of a plurality of pixel electrodes.

The opposing electrode 280 may include a transparent conductive layer formed of transparent conductive oxide such as indium tin oxide (ITO), indium oxide (In2O3), or indium zinc oxide (IZO). The pixel electrode may be used as an anode, and the opposing electrode 280 may be used as a cathode. Depending on the embodiment, the polarities of the electrodes may be reversed.

The opposing electrode 280 may be disposed on the display area DA and may be disposed on an entire surface of the display area DA. The opposing electrode 280 may be formed integrally to cover a plurality of pixels.

The first organic insulating layer 205 and the second organic insulating layer 206 may be etched in the peripheral area PA, such that outer edges of the first organic insulating layer 205 and the second organic insulating layer 206 may be disposed in the peripheral area PA. In the peripheral area PA, the side surfaces of the outer edges of the first organic insulating layer 205 and the second organic insulating layer 206 may form a continuous surface. In the peripheral area PA, the side surfaces of the first organic insulating layer 205 and the second organic insulating layer 206 may be coplanar.

A touch routing line 240a may be disposed in the peripheral area PA. For example, the touch routing line 240a may receive a signal received from the touch sensor layer 400 and may transmit the received signal to a touch circuit (not shown). For example, the touch routing line 240a may include the same material as the first conductive layer 240 and may be disposed in the same layer as the first conductive layer 240. In another example, unlike what is shown in the drawings, the touch routing line 240a may include the same material as the second conductive layer 250 and may be disposed in the same layer as the second conductive layer 250.

The display layer 200 may refer to various components disposed between the above-described substrate 100 and the encapsulation layer 300 to be described below. For example, in the specification, the display layer 200 may include all or some of the components from the buffer layer 201 on the substrate 100 to the opposing electrode 280 as depicted in FIG. 4.

An encapsulation layer 300 may be disposed on the opposing electrode 280. The encapsulation layer 300 may cover the entire display area DA and may be disposed to extend toward the peripheral area PA to cover at least a portion of the peripheral area PA. For example, the encapsulation layer 300 may be disposed to cover the entire touch routing line 240a described above.

The encapsulation layer 300 may include a first inorganic encapsulation layer 301, a second inorganic encapsulation layer 303, and an organic encapsulation layer 302 interposed therebetween. The first inorganic encapsulation layer 301 and the second inorganic encapsulation layer 303 may include one or more inorganic materials of aluminum oxide, titanium oxide, tantalum oxide, hafnium oxide, zinc oxide, silicon oxide, silicon nitride, and silicon oxynitride.

The first inorganic encapsulation layer 301 and the second inorganic encapsulation layer 303 may each have a single-layer structure or a multiple-layer structure including the aforementioned materials. The first inorganic encapsulation layer 301 and the second inorganic encapsulation layer 303 may include the same material or different materials. The thicknesses of the first inorganic encapsulation layer 301 and the second inorganic encapsulation layer 303 may be the same or different from each other. The thickness of the first inorganic encapsulation layer 301 may be greater than the thickness of the second inorganic encapsulation layer 303. In other embodiments, the thickness of the second inorganic encapsulation layer 303 may be greater than the thickness of the first inorganic encapsulation layer 301, or the thicknesses of the first inorganic encapsulation layer 301 and the second inorganic encapsulation layer 303 may be equal to each other.

The organic encapsulation layer 302 may include monomer-based materials or polymer-based materials. The polymer-based materials may include acrylic resin, epoxy resin, polyimide, and polyethylene. For example, the organic encapsulation layer 302 may include acrylate.

For example, according to an embodiment, a method for manufacturing a display module may include forming a display layer 200 on a substrate 100 that is divided into a display area DA and a peripheral area PA, and forming an encapsulation layer 300 on the display layer 200.

The forming of the display layer 200 on the substrate 100 may mean sequentially disposing or forming components of the display layer 200. For example, the forming of the display layer 200 on the substrate 100 may include sequentially forming a buffer layer 201, a semiconductor layer 210, a first gate insulating layer 202, a first gate layer 220, a second gate insulating layer 203, a second gate layer 230, an interlayer insulating film 204, a first conductive layer 240, a first organic insulating layer 205, a second conductive layer 250, a second organic insulating layer 206, a pixel electrode layer 260, and a pixel defining layer 207 on the substrate 100. When necessary, each layer may be etched according to a predetermined pattern. The forming the display layer 200 on the substrate 100 may further include forming an intermediate layer 270 and an opposing electrode 280.

The forming the encapsulation layer 300 on the display layer 200 may mean sequentially disposing or forming components of the encapsulation layer 300. For example, the forming of the encapsulation layer 300 on the display layer 200 may be a process of sequentially forming a first inorganic encapsulation layer 301, an organic encapsulation layer 302, and a second inorganic encapsulation layer 303.

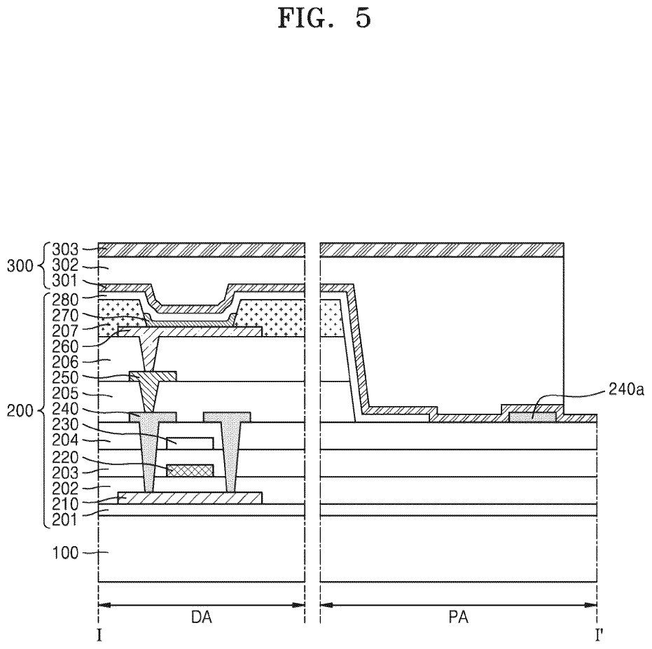

Referring to FIG. 4 and FIG. 5, an edge portion SA of the encapsulation layer 300 may be removed. For example, according to an embodiment, the method for manufacturing a display module 11 may further include removing an edge portion SA of the encapsulation layer 300. The edge portion SA may mean a portion of the encapsulation layer 300 disposed outside the touch routing line 240a. Photolithography and etching processes may be used to remove the edge portion SA of the encapsulation layer 300.

As the edge portion SA of the encapsulation layer 300 is removed, a step difference may be formed in the encapsulation layer 300. The step difference of the encapsulation layer 300 may be formed by an upper surface of the encapsulation layer 300 and a cross-section of the encapsulation layer 300 exposed after removing the edge portion SA. The step difference of the encapsulation layer 300 may have a height equal to the height of the encapsulation layer 300.

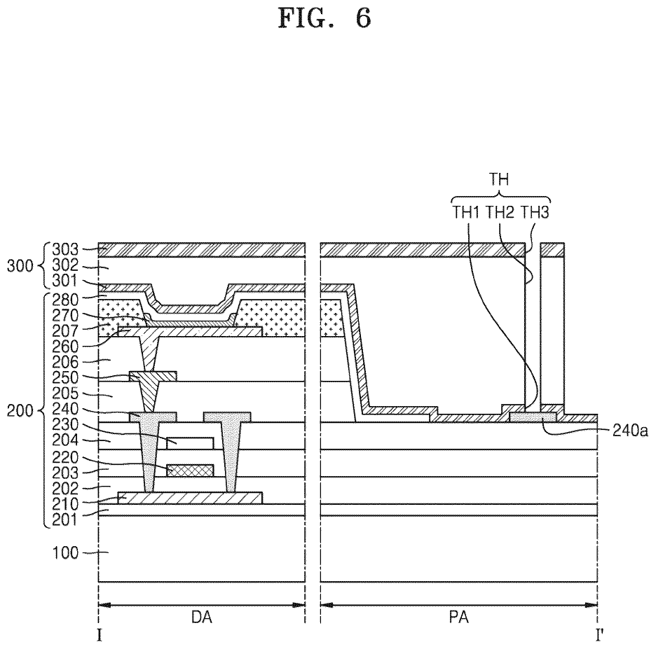

Referring to FIG. 6, after the edge portion SA of the encapsulation layer 300 is removed, a through hole TH extending through the encapsulation layer 300 may be formed. The through hole TH may extend through the thickness of the encapsulation layer 300 to reach an upper surface of the touch routing line 240a.

For example, according to an embodiment, the method for manufacturing a display module 11 may further include forming a through hole TH in a remaining portion of the encapsulation layer 300 in the peripheral area PA. The forming of the through hole TH in the remaining portion of the encapsulation layer 300 in the peripheral area PA may use an etching process using a hard mask.

For example, the through hole TH may extend through the thickness of the first inorganic encapsulation layer 301, the second inorganic encapsulation layer 303, and the organic encapsulation layer 302. For example, the depth of a first through hole TH1 may be the same as the thickness of the first inorganic encapsulation layer 301, the depth of a second through hole TH2 may be the same as the thickness of the organic encapsulation layer 302, and the depth of a third through hole TH3 may be the same as the thickness of the second inorganic encapsulation layer 303. For example, the first through hole TH1, the second through hole TH2, and the third through hole TH3 may be aligned to together form a continuous through hole TH of the encapsulation layer 300 described above. For example, inner surfaces of each of the first through hole TH1, the second through hole TH2, and the third through hole TH3 may form a continuous surface.

For example, when the through hole TH (or the first through hole TH1) is formed, an upper surface of the touch routing line 240a may be exposed. The through hole TH is formed on the touch routing line 240a, and the through hole TH may be formed in a direction perpendicular to the upper surface of the touch routing line 240a.

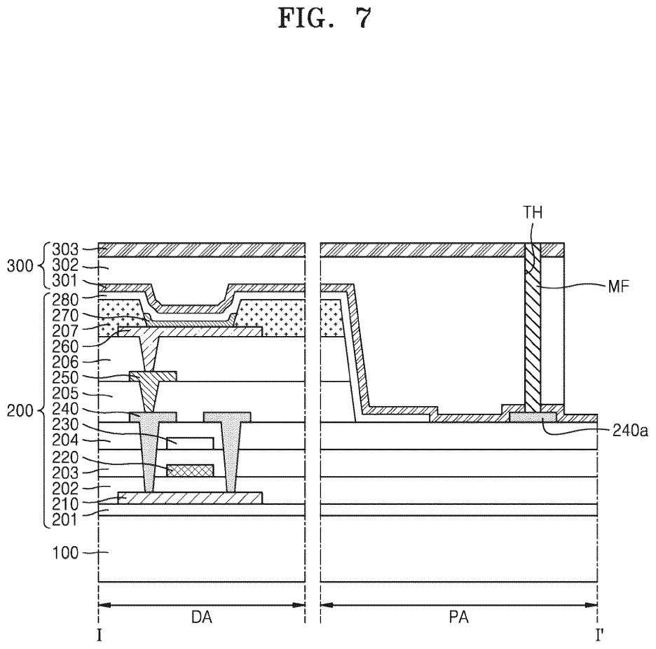

Referring to FIG. 7, a conductive material may be injected into the through hole TH formed in the encapsulation layer 300. For example, according to an embodiment, the method for manufacturing a display module 11 may further include injecting a conductive material into the through hole TH.

When the conductive material is injected into the through hole TH, a conductive body MF may be formed. The conductive body MF may have a shape corresponding to a shape of the through hole TH. The conductive body MF may (directly) contact an upper surface of the touch routing line 240a through the through hole TH (or the first through hole TH1).

The conductive body MF may include one or more metals selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). Or, the conductive body MF may include indium tin oxide (ITO), indium oxide (In2O3), or indium zinc oxide (IZO).

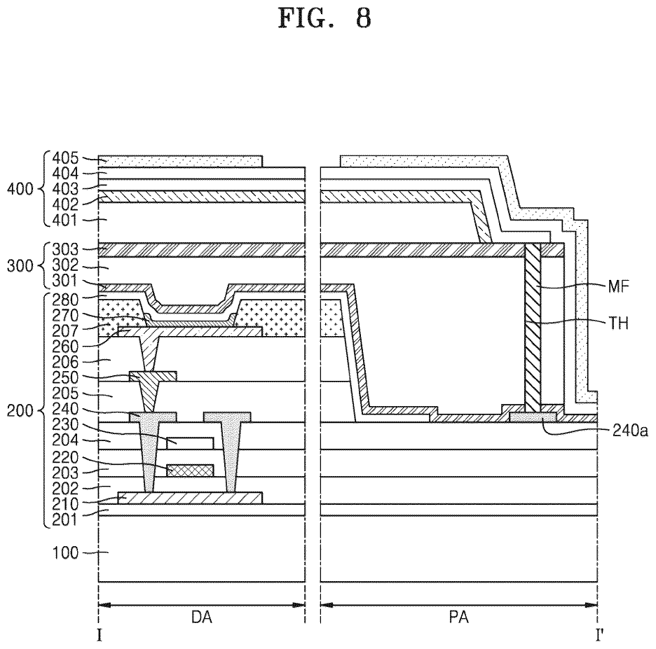

Referring to FIG. 8, a touch sensor layer 400 may be disposed on the encapsulation layer 300. For example, according to an embodiment, the method for manufacturing a display module 11 may further include forming a touch sensor layer 400 on the encapsulation layer 300. For example, the touch sensor layer 400 may (directly) contact the conductive material (for example, the conductive body MF) injected into the through hole TH. For example, the conductive material may be injected into the first through hole TH1 to the third through hole TH3. For example, the touch sensor layer 400 may cover the side surface of the encapsulation layer.

The touch sensor layer 400 may include a touch planarization layer 401, a first touch insulating layer 402, a first touch conductive layer 403, a second touch insulating layer 404, and a second touch conductive layer 405. In some embodiments, another touch insulating layer that is not explicitly show in the drawings may be further disposed on the second touch conductive layer 405.

The touch planarization layer 401 may be disposed on the encapsulation layer 300. The touch planarization layer 401 may include organic material. For example, the touch planarization layer 401 may serve as a planarization film by covering the upper portion of the encapsulation layer 300 and having a substantially planar upper surface. For example, the touch planarization layer 401 may include organic materials such as acryl, benzocyclobutene (BCB), or hexamethyldisiloxane (HMDSO).

The first touch insulating layer 402 may be disposed on the touch planarization layer 401. In some embodiments, the touch planarization layer 401 may be omitted, and when the touch planarization layer 401 is omitted, the first touch insulating layer 402 may be disposed on the encapsulation layer 300.

The first touch insulating layer 402 may include inorganic material or organic material, and may be provided as a single layer or multiple layers. The organic material may include at least one material selected from the group consisting of acrylic resin, methacrylic resin, polyisoprene, vinyl resin, epoxy resin, urethane resin, cellulose resin, and perylene resin. The inorganic material may include at least one material selected from the group consisting of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride.

The first touch conductive layer 403 may be disposed on the first touch insulating layer 402. The first touch conductive layer 403 may include a metal layer or a transparent conductive layer. The metal layer may include, for example, molybdenum (Mo), silver (Ag), titanium (Ti), copper (Cu), aluminum (Al), and alloys of molybdenum, silver, titanium, copper, and aluminum. The transparent conductive layer may include transparent conductive oxides such as indium tin oxide (ITO), indium zinc oxide (IZO), zinc oxide (ZnO), indium tin zinc oxide (ITZO). The first touch conductive layer 403 may be provided as a single layer or multiple layer structure. For example, the first touch conductive layer 403 may have a three-layer structure of Ti/Al/Ti.

The first touch conductive layer 403 may include a plurality of patterns. The first touch conductive layer 403 may include first conductive patterns. The first conductive patterns may form sensor electrodes.

The second touch insulating layer 404 may be disposed on the first touch conductive layer 403. The second touch insulating layer 404 may include inorganic material or organic material. The organic material may include at least one material selected from the group consisting of acrylic resin, methacrylic resin, polyisoprene, vinyl resin, epoxy resin, urethane resin, cellulose resin, and perylene resin. The inorganic material may include at least one material selected from the group consisting of silicon nitride, aluminum nitride, zirconium nitride, titanium nitride, hafnium nitride, tantalum nitride, silicon oxide, aluminum oxide, titanium oxide, tin oxide, cerium oxide, and silicon oxynitride.

The second touch conductive layer 405 may be disposed on the second touch insulating layer 404. The second touch conductive layer 405 may include a metal layer or a transparent conductive layer. The metal layer may include, for example, molybdenum (Mo), silver (Ag), titanium (Ti), copper (Cu), aluminum (Al), and alloys of molybdenum, silver, titanium, copper, and aluminum. The transparent conductive layer may include transparent conductive oxides such as indium tin oxide (ITO), indium zinc oxide (IZO), zinc oxide (ZnO), indium tin zinc oxide (ITZO). The second touch conductive layer 405 may be provided as a single layer or multiple layer structure. For example, the second touch conductive layer 405 may have a triple-layer structure of Ti/Al/Ti. The second touch conductive layer 405 includes a plurality of patterns. The second touch conductive layer 405 may be understood to include second conductive patterns. The second conductive patterns may form sensor electrodes.

The first touch conductive layer 403 and the second touch conductive layer 405 may be electrically connected through a contact hole (not shown) formed in the second touch insulating layer 404. According to an embodiment, the first touch conductive layer 403 and the second touch conductive layer 405 may have a mesh structure in a plan view to allow light emitted from an organic light emitting diode (OLED) to pass through. The first touch conductive layer 403 and the second touch conductive layer 405 may be in a light emitting region (for example, the light emitting region may be defined by the pixel defining layer 207)

As illustrated in FIG. 8, the touch sensor layer 400 or at least one layer of the touch sensor layer 400 may cover the side surface at the edge of the encapsulation layer 300. For example, after the edge portion SA of the encapsulation layer 300 is removed, the side surface of the encapsulation layer 300 may be exposed. In some embodiments, the side surface of the encapsulation layer 300 that is exposed may be covered by at least one layer of the touch sensor layer 400.

For example, when the edge portion SA of the encapsulation layer 300 is removed, a component (for example, an interlayer insulating film) below the edge portion SA of the encapsulation layer 300 may be exposed. An upper surface of the exposed component may be covered by the touch sensor layer 400.

For example, the touch planarization layer 401 is disposed on the encapsulation layer 300, and the touch planarization layer 401 may cover at least a portion of an upper surface of the encapsulation layer 300. The first touch insulating layer 402 may cover an upper surface and a side surface of the touch planarization layer 401. The first touch conductive layer 403 may cover an upper surface and a side surface of the first touch insulating layer 402. The first touch conductive layer 403 may cover at least a portion of areas of the upper surface of the encapsulation layer 300 that are not covered by the touch planarization layer 401 and the first touch insulating layer 402.

For example, the through hole TH formed in the encapsulation layer 300 may not be covered by the touch planarization layer 401 and the first touch insulating layer 402. The conductive material (for example, the conductive body MF) injected into the through hole TH formed in the encapsulation layer 300 may not be covered by the touch planarization layer 401 and the first touch insulating layer 402. The first touch conductive layer 403 may cover an upper surface of the conductive material (for example, the conductive body MF) that fills the through hole TH extending through the encapsulation layer 300, or may (directly) contact an upper surface of the conductive material (for example, the conductive body) that fills the through hole TH extending through the encapsulation layer 300. As a result, the first touch conductive layer 403 may be electrically connected to the touch routing line 240a through the conductive body MF. The first touch conductive layer 403 may not cover the side surface of the encapsulation layer 300.

For example, the second touch insulating layer 404 may cover the upper surface and side surface of the first touch conductive layer 403, cover areas of the upper surface of the encapsulation layer 300 that are not covered by the first touch insulating layer 402 and the first touch conductive layer 403, and cover the side surface of the encapsulation layer 300. The second touch insulating layer 404 may cover an upper surface of a component (for example, the encapsulation layer 301) that is exposed upon removal of the edge portion SA of the encapsulation layer 300. As a result, the second touch insulating layer 404 may have an outline that follows a step difference formed by the encapsulation layer 300 whose edge portion SA is removed.

The second touch conductive layer 405 may cover an upper surface of the second touch insulating layer 404. As a result, the second touch conductive layer 405 may have a stepped shape that follows the contours of the second touch insulating layer 404. For example, the second touch conductive layer 405 may be electrically connected to the first touch conductive layer 403 through a contact hole (not shown) formed in the second touch insulating layer 404, and as a result, the second touch conductive layer 405 may be electrically connected to the conductive body MF and the touch routing line 240a.

According to an embodiment, a display module 11 may include a substrate 100 divided into a display area DA and a peripheral area PA, a display layer 200 disposed on the substrate 100, and an encapsulation layer 300 disposed on the display layer 200 and having a step difference with respect to the display layer 200. The “step difference of the encapsulation layer 300” as used herein refers to a step difference formed by removing an edge portion SA of the encapsulation layer 300.

According to an embodiment, the display module 11 may include a conductive body MF including a conductive material that extends through the encapsulation layer 300 in the peripheral area PA, and a touch sensor layer 400 formed on the encapsulation layer 300, contacting an upper surface of the conductive body MF, and covering an upper surface and a side surface of the encapsulation layer 300.

According to an embodiment, the display layer 200 may include a semiconductor layer 210 disposed on the substrate 100, a gate layer 220, 230 disposed on the semiconductor layer 210, a first conductive layer 240 disposed on the gate layer 220, 230, a second conductive layer 250 disposed on the first conductive layer 240, and a pixel electrode layer 260 disposed on the second conductive layer 250. A portion of the first conductive layer 240 may be a touch routing line 240a. The touch routing line 240a may be electrically connected to a touch circuit (not shown).

According to an embodiment, the encapsulation layer 300 may include a first inorganic encapsulation layer 301 disposed on the display layer 200 and having a first through hole TH1, an organic encapsulation layer 302 disposed on the first inorganic encapsulation layer and having a second through hole TH2, and a second inorganic encapsulation layer 303 disposed on the organic encapsulation layer and having a third through hole TH3. Inner surfaces of each of the first through hole TH1 to the third through hole TH3 are aligned to form a continuous hole extending through the first inorganic encapsulation layer 301, the organic encapsulation layer 302, and the second inorganic encapsulation layer 303, and the conductive body MF may be continuously disposed inside the first through hole TH1, the second hole TH2, and the third through hole TH3.

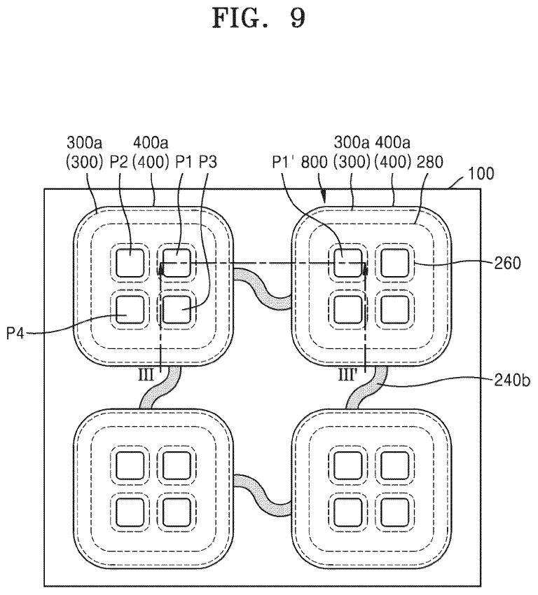

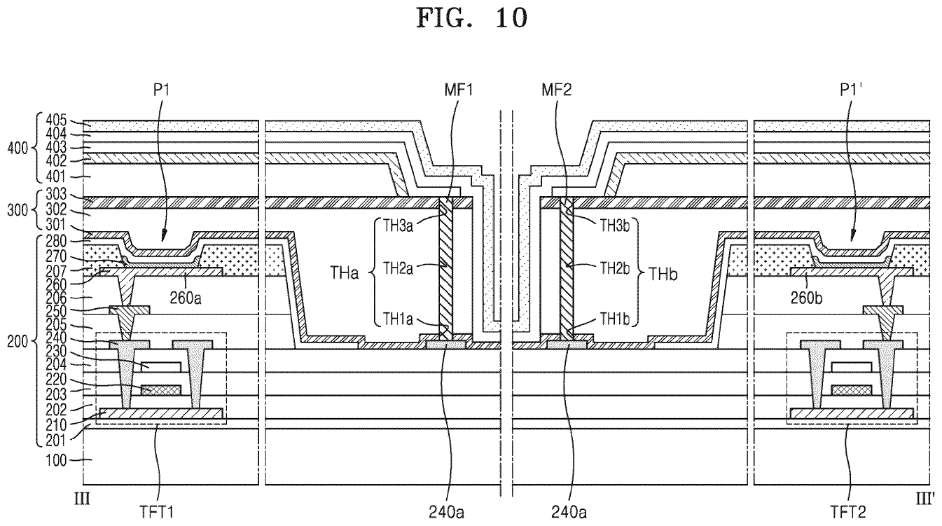

FIG. 9 is a plan view schematically illustrating a stretchable display module according to an embodiment, and FIG. 10 is a cross-sectional view illustrating an example of a cross-section taken along line III-III′. For convenience of description, only some light emitting units may be illustrated. For reference, descriptions of FIGS. 9 and 10 that are identical to or overlap with descriptions of FIGS. 1 to 8 may be omitted.

As illustrated in FIG. 9, a plurality of light emitting units 800 may be disposed on the substrate 100. The substrate 100 used in the stretchable display module 11 may be a stretchable substrate that stretches in at least one direction in at least a portion of the substrate.

Each of the plurality of light emitting units 800 may include a plurality of sub-pixels P1, P2, P3, P4. For example, the first sub-pixel P1 may generate light of a first wavelength band (for example, green visible light band), the second sub-pixel P2 may generate light of a second wavelength band (for example, red visible light band), the third sub-pixel P3 may generate light of a third wavelength band (for example, blue visible light band), and the fourth sub-pixel P4 may generate white light. However, the numbers of sub-pixels included in the light emitting unit 800 and the types of light generated by the sub-pixels are not limited to the above examples and various modifications are possible.

Each of the plurality of light emitting units 800 may be sealed by the encapsulation layer 300. For example, in case of the stretchable display module 11, the encapsulation layer 300 may include a sealing portion 300a that seals one light emitting unit 800. Since one sealing portion 300a seals one light emitting unit 800, the encapsulation layer may include a plurality of sealing portions 300a for sealing a plurality of light emitting units 800.

The plurality of sealing portions 300a may be covered by the touch sensor layer 400 described above. For example, the touch sensor layer 400 may include a touch sensor portion 400a for covering each of the plurality of sealing portions 300a. For example, one sealing portion 300a may be covered by one touch sensor portion 400a, and for covering each sealing portion with a corresponding touch sensor portion, the touch sensor layer 400 may include a plurality of touch sensor portions 400a. Therefore, in a plan view, the sealing portion 300a may be disposed within the touch sensor portion 400a, and a shape of the touch sensor portion 400a in the plan view may correspond to a shape of the sealing portion 300a.

In some embodiments, unlike what is shown in FIG. 9, a touch sensor layer 400 may be formed continuously to cover a plurality of sealing portions 300a. For example, the touch sensor layer 400 may be continuously disposed on the sealing portion 300a and the area between sealing portions 300a.

A stretchable wiring 240b electrically connecting between the plurality of light emitting units 800 may be disposed on the substrate 100. The stretchable wiring 240b may have various structural configurations to have stretchability, and these various structural configurations may be conventional structures known in the art.

As illustrated in FIG. 10, the first sub-pixel P1 may include a first thin film transistor TFT1 disposed on the substrate 100 and a first pixel electrode 260a disposed on the first thin film transistor TFT1. The first pixel electrode 260a and the first thin film transistor TFT1 may be components included in the display layer 200.

For example, the first prime sub-pixel P1′ may include a second thin film transistor TFT2 disposed on the substrate 100 and a second pixel electrode 260b disposed on the second thin film transistor TFT2. The second pixel electrode 260b and the second thin film transistor TFT2 may be components included in the display layer 200.

The first sub-pixel P1 and the first prime sub-pixel P1′ may be sealed by separate sealing portions 300a. Based on the space between the sealing portions 300a, the first sub-pixel P1 and the first prime sub-pixel P1′ may be disposed in positions that are symmetrical with respect to a virtual line between them.

A step difference or an opening formed by removing a portion of the encapsulation layer 300 may be disposed or defined between the first sub-pixel P1 and the first prime sub-pixel P1′. Since the touch sensor layer 400 is formed along the step difference of the encapsulation layer 300, the touch sensor layer 400 may also have a step difference that follows the contours of the step difference of the encapsulation layer 300 between the first sub-pixel P1 and the first prime sub-pixel P1′.

Between the first sub-pixel P1 and the first prime sub-pixel P1′, a through hole THa may be disposed around the first sub-pixel P1, and a through hole THb may be disposed around the first prime sub-pixel P1′. When a conductive material fills the through hole THa around the first sub-pixel P1, a first conductive body MF1 may be formed, and the first conductive body MF1 may directly contact a touch routing line 240a below. When a conductive material fills the through hole THb around the first prime sub-pixel P1′, a second conductive body MF2 may be formed, and the second conductive body MF2 may directly contact the touch routing line 240a below. The first conductive body MF1 and the second conductive body MF2 may directly contact the touch sensor layer 400.

Although the positions of the through holes THa, THb have been described in reference to the first sub-pixel P1 and the first prime sub-pixel P1′ above, this is for convenience of description. The positions of the through holes THa, THb may be described with respect to the first pixel electrode 260a and the second pixel electrode 260b instead of the first sub-pixel P1 and the first prime sub-pixel P1′, and since the first pixel electrode 260a and the second pixel electrode 260b are components included in the first sub-pixel P1 and the first prime sub-pixel P1′, the positions of the through holes THa, THb may be inherently understood.

In the display module 11 of FIG. 10, the through hole TH may be disposed in the display area DA in a plan view. That is, the position where the through hole TH is disposed may not be in the peripheral area PA. In the stretchable display module 11, since sealing may be performed for each sealing portion 300a, the through hole TH may be disposed between the sealing portions 300a.

For example, the method for manufacturing the display module of FIG. 10 may include forming a display layer 200 including a first pixel electrode 260a on a substrate 100, forming an encapsulation layer 300 on the display layer 200, forming through holes THa, THb through the encapsulation layer 300 such that the through holes do not overlap with the first pixel electrode 260a, disposing a conductive material into the through holes THa, THb, and forming a touch sensor layer 400 on the encapsulation layer 300.

The method for manufacturing the display module 11 of FIG. 10 may proceed according to the sequence of the layers shown in FIG. 10, and specific details may be replaced by the descriptions of FIGS. 4 to 8. One of ordinary skill in the art may easily understand the content of the manufacturing method of FIG. 10 based on the descriptions of FIGS. 4 to 8.

Based on the above descriptions, an electronic device 1 including a display module according to an embodiment will be described in detail below.

The display module 11 according to the embodiment may be incorporated into various electronic devices. The electronic device according to an embodiment includes the display device described above, and may further include modules or devices having additional functions other than the display module 11.

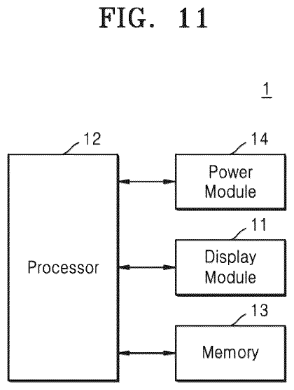

FIG. 11 is a block diagram of an electronic device according to an embodiment.

Referring to FIG. 11, an electronic device 1 according to an embodiment may include a display module 11, a processor 12, a memory 13, and a power module 14. In the specification, the display module 11 of FIG. 11 may be inherently understood as the same concept as the display module 11 described above. Therefore, the display module of FIG. 11 may be any one of the examples of the display module 11 mentioned in FIGS. 1 to 10.

The processor 12 may include at least one of a central processing unit (CPU), an application processor (AP), a graphic processing unit (GPU), a communication processor (CP), an image signal processor (ISP), and a controller.

The memory 15 may store data information necessary for operation of the processor 12 or the display module 11. When the processor 12 executes an application stored in the memory 15, image data signals and/or input control signals are transmitted to the display module 11, and the display module 11 may process the received signals to output image information through a display screen.

The power module 14 may include a power supply module such as a power adapter or a battery device, and a power conversion module that converts power supplied by the power supply module to generate power necessary for operation of the electronic device 1.

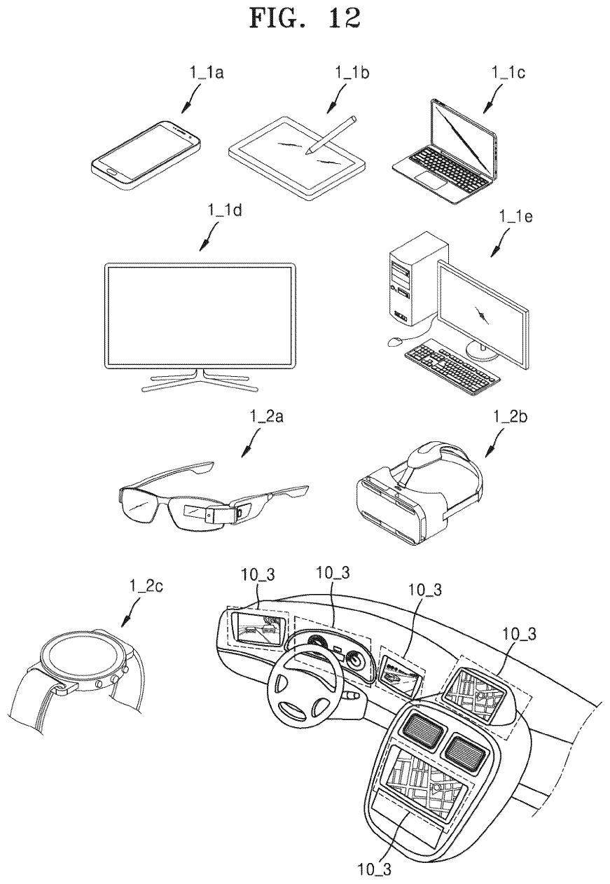

FIG. 12 depicts schematic views of electronic devices according to various embodiments.

Referring to FIG. 12, various electronic devices to which the display device according to the embodiments is applied may include not only image display electronic devices such as a smartphone 1_1a, a tablet PC 1_1b, a laptop 1_1c, a TV 1_1d, a desktop monitor 1_1e, but also wearable electronic devices including a display module such as smart glasses 1_2a, a head mounted display 1_2b, a smart watch 1_2c, and automotive electronic devices 10_3 including a display module such as an instrument panel, a center fascia, a Center Information Display (CID) disposed on a dashboard, and a room mirror display of a vehicle.

According to an embodiment, an electronic device 1 may include a memory 13 storing data information, a processor 12 generating data signals and/or control signals based on the data information, and a display module 11 operating based on the data signals and/or control signals.

According to an embodiment, the display module 11 may include a substrate 100 divided into a display area DA and a peripheral area PA, a display layer 200 disposed on the substrate 100, an encapsulation layer 300 disposed on the display layer 200 and having a step difference with respect to the display layer 200, and a conductive body MF including a conductive material and extending through the encapsulation layer 300 in the peripheral area. The display module 11 may further include a touch sensor layer 400 formed on the encapsulation layer 300, contacting an upper surface of the conductive body MF, and covering an upper surface and a side surface of the encapsulation layer 300.

According to an embodiment, the display layer 200 may include a semiconductor layer 210 disposed on the substrate, a gate layer 220, 230 disposed on the semiconductor layer, a first conductive layer 240 disposed on the gate layer 220, 230, a second conductive layer 250 disposed on the first conductive layer 240, and a pixel electrode layer 260 disposed on the second conductive layer 250.

According to an embodiment, a lower surface of the conductive body MF may contact a portion of the first conductive layer 240, and the portion of the first conductive layer 240 may be a touch routing line 240a.

While embodiments have been described with reference to the drawings, these are exemplary only, and those skilled in the art will understand that various modifications and equivalent other embodiments are possible therefrom. Therefore, the true technical scope of protection should be determined by the technical spirit of the appended claims.

According to an embodiment as described above, a method for manufacturing a display module for implementing a slim bezel, a display module, and an electronic device including the display module may be implemented. Of course, the scope of the embodiments is not limited by such effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A method of manufacturing a display module comprising a substrate having a display area and a peripheral area, the method comprising:
forming a display layer on the substrate;
forming an encapsulation layer on the display layer;
removing an edge portion of the encapsulation layer, leaving a remaining portion of the encapsulation layer;
forming a through hole through the remaining portion of the encapsulation layer in the peripheral area;
disposing a conductive material in the through hole; and
forming a touch sensor layer on the remaining portion of the encapsulation layer.

2. The method of claim 1, wherein the touch sensor layer contacts the conductive material that is disposed in the through hole.

3. The method of claim 2, wherein the display layer comprises:
a semiconductor layer on the substrate, a gate layer on the semiconductor layer, a first conductive layer on the gate layer, a second conductive layer on the first conductive layer, and a pixel electrode on the second conductive layer.

4. The method of claim 3, wherein the conductive material contacts a portion of the first conductive layer of the display layer.

5. The method of claim 1, wherein the forming of the touch sensor layer comprises covering a side surface of the remaining portion of the encapsulation layer with the touch sensor layer.

6. The method of claim 1, wherein the forming of the through hole comprises using a hard mask.

7. The method of claim 1, wherein the encapsulation layer comprises:
a first inorganic encapsulation layer disposed on the display layer, an organic encapsulation layer disposed on the first inorganic encapsulation layer, and a second inorganic encapsulation layer disposed on the organic encapsulation layer.

8. The method of claim 7, wherein the forming of the through hole comprises
forming a first through hole in the first inorganic encapsulation layer, forming a second through hole in the organic encapsulation layer, and forming a third through hole in the second inorganic encapsulation layer.

9. The method of claim 8, wherein the first through hole, the second through hole, and the third through hole align to form a continuous through hole.

10. The method of claim 9, wherein the conductive material is disposed in the first through hole, the second through hole, and the third through hole.

11. A display module comprising:
a substrate having a display area and a peripheral area;
a display layer disposed on the substrate;
an encapsulation layer disposed on the display layer and having a step difference with respect to the display layer;
a conductive body including a conductive material extending through the encapsulation layer in the peripheral area; and
a touch sensor layer disposed on the encapsulation layer, contacting an upper surface of the conductive body, and covering an upper surface and a side surface of the encapsulation layer.

12. The display module of claim 11, wherein the display layer comprises:
a semiconductor layer disposed on the substrate;
a gate layer disposed on the semiconductor layer;
a first conductive layer disposed on the gate layer;
a second conductive layer disposed on the first conductive layer; and
a pixel electrode disposed on the second conductive layer.

13. The display module of claim 12, wherein a lower surface of the conductive body contacts a touch routing line disposed in a same layer as the first conductive layer.

14. The display module of claim 12, wherein the conductive body is distanced from the pixel electrode in plan view.

15. The display module of claim 12, wherein the pixel electrode is a first pixel electrode, further comprising:
a second pixel electrode disposed in a same layer as the first pixel electrode, wherein the conductive body is disposed between the first pixel electrode and the second pixel electrode.

16. The display module of claim 11, wherein the encapsulation layer comprises:
a first inorganic encapsulation layer disposed on the display layer and having a first through hole;
an organic encapsulation layer disposed on the first inorganic encapsulation layer and having a second through hole; and
a second inorganic encapsulation layer disposed on the organic encapsulation layer and having a third through hole.

17. The display module of claim 16, wherein the first through hole, the second through hole, and the third through hole align to form a continuous through hole, and
the conductive body is disposed inside the first through hole, the second through hole, and the third through hole.

18. The method of claim 3, wherein the through hole does not overlap with the pixel electrode.

19. The method of claim 18, wherein the pixel electrode is a first pixel electrode, further comprising a second pixel electrode disposed in a same layer as the first pixel electrode, and
the through hole is disposed between the first pixel electrode and the second pixel electrode.

20. An electronic device comprising:
a memory storing data information;
a processor generating a data signal and/or a control signal based on the data information; and
a display module operating based on the data signal and/or the control signal,
wherein the display module comprises:
a substrate having a display area and a peripheral area;
a display layer disposed on the substrate;
an encapsulation layer disposed on the display layer and having a step difference with respect to the display layer;
a conductive body including a conductive material extending through the encapsulation layer in the peripheral area; and
a touch sensor layer disposed on the encapsulation layer, contacting an upper surface of the conductive body, and covering an upper surface and a side surface of the encapsulation layer.
